(19) United States
(12) Patent Application Publication
(10) Pub. No.: US 2021/0103791 A1
(43) Pub. Date: Apr. 8, 2021

(54) CARD TYPE SOLID STATE DRIVE

(71) Applicant: SAMSUNG ELECTRONICS CO., LTD., Suwon-si (KR)

(72) Inventors: Injae LEE, Seoul (KR); Sangsub SONG, Suwon-si (KR); Minkyung KOOK, Suwon-si (KR); Kihong JEONG, Jeonju-si (KR)

(21) Appl. No.: 16/935,374

(22) Filed: Jul. 22, 2020

(30) Foreign Application Priority Data
Oct. 2, 2019 (KR) 10-2019-0122507
Dec. 18, 2019 (KR) 10-2019-0170202

(51) Int. Cl. G06K 19/077; G11C 5/14; G11C 7/10

(52) U.S. Cl. CPC G06K 19/07732; G11C 7/10; G11C 5/14

(57) ABSTRACT

A card-type solid state drive (SSD) including: a substrate having an insertion edge, a first edge, and a second edge, wherein the first edge and the second edge are adjacent to the insertion edge; a protrusion on the first edge; first column terminals adjacent to the insertion edge and including a first power terminal and first data terminals; second column terminals farther apart from the insertion edge than the first column terminals and including a second power terminal and second data terminals; and third column terminals farther apart from the insertion edge than the second column terminals and including a third power terminal and command terminals, wherein the first, second and third power terminals are arranged along the first edge.

### CROSS-REFERENCE TO RELATED APPLICATIONS

This application claims priority under 35 U.S.C. § 119 to Korean Patent Application No. 10-2019-0122507, filed on Oct. 2, 2019 and Korean Patent Application No. 10-2019-0170202, filed on Dec. 18, 2019, the disclosures of which are incorporated by reference herein in their entireties.

### TECHNICAL FIELD

The inventive concept relates to a card-type solid state drive (SSD), and more particularly, to a card-type SSD capable of maximizing the utilization of a card area and supplying electrically stable power.

### DISCUSSION OF RELATED ART

Memory cards are electronic data storage devices used for storing digital information. Memory cards are widely used in electronic devices such as mobile phones, notebook computers, etc. Memory cards have various sizes depending on their application. In addition, memory cards have been made smaller, faster, and with larger storage capacities over time. However, in a memory device having a large storage capacity, a method to supply power more stably and operate at a high speed may be employed.

### SUMMARY

According to an exemplary embodiment of the inventive concept, there is provided a card-type solid state drive (SSD) including: a substrate having an insertion edge, a first edge, and a second edge, wherein the first edge and the second edge are adjacent to the insertion edge; a protrusion on the first edge; first column terminals adjacent to the insertion edge and including a first power terminal and first data terminals; second column terminals farther apart from the insertion edge than the first column terminals and including a second power terminal and second data terminals; and third column terminals farther apart from the insertion edge than the second column terminals and including a third power terminal and command terminals, wherein the first, second and third power terminals are arranged along the first edge.

According to an exemplary embodiment of the inventive concept, there is provided a card-type SSD including: a substrate having an insertion edge extending in a first direction, a first edge, and a second edge, wherein the first edge and the second edge are adjacent to the insertion edge and extend in a second direction perpendicular to the first direction; a protrusion on the first edge; first column terminals linearly arranged in the first direction and including a first power terminal and first data terminals; second column terminals spaced apart from the first column terminals in the second direction, linearly arranged in the first direction, and including a second power terminal and second data terminals; and third column terminals spaced apart from the first and second column terminals in the second direction, linearly arranged in the first direction, and including a third power terminal and command terminals, wherein the first, second and third power terminals are linearly arranged in the second direction.

According to an exemplary embodiment of the inventive concept, a card-type SSD includes: a substrate having an insertion edge extending in a first direction, a first edge, and a second edge, wherein the first edge and the second edge are adjacent to the insertion edge and extend in a second direction perpendicular to the first direction; a protrusion on the first edge; first column terminals arranged adjacent to the insertion edge and including a first power terminal, a reference clock terminal, first data terminals, and a first spare terminal; second column terminals arranged farther apart from the insertion edge than the first column terminals and including a second power terminal, second data terminals, and a second spare terminal; and third column terminals arranged farther apart from the insertion edge than the second column terminals and including third power terminals, command terminals, test terminals, and a third spare terminal, wherein the first, second and third power terminals are linearly arranged in the second direction and are adjacent to the first edge.

According to an exemplary embodiment of the inventive concept, there is provided a card-type SSD including: a substrate having a first edge, a second edge, and a third edge, wherein the second edge and the third edge face each other and are connected to the first edge; a protrusion on the second edge or the third edge; first terminals arranged in a first direction parallel to the first edge, the first terminals including a first power terminal and first data terminals; second terminals arranged in the first direction, the second terminals including a second power terminal and second data terminals; and third terminals arranged in the first direction, the third terminals including a third power terminal and command terminals, wherein the first terminals are spaced apart from the first edge by a first distance, the second terminals are spaced apart from the first edge by a second distance and the third terminals are spaced apart from the first edge by a third distance, wherein the first distance, the second distance and the third distance are different from each other.

### BRIEF DESCRIPTION OF THE DRAWINGS

The above and other features of the inventive concept will be more clearly understood by describing in detail exemplary embodiments thereof in conjunction with the accompanying drawings in which:

FIG. 1 is a perspective view showing examples of storage devices;

FIG. 2 is a plan view showing various form factors of a solid state drive (SSD);

FIGS. 3A, 3B and 3C are views of a card-type SSD according to an exemplary embodiment of the inventive concept;

FIGS. 4, 5, 6, 7, 8 and 9 are bottom views of a card-type SSD according to an exemplary embodiment of the inventive concept;

FIG. 10 is a schematic view of a system using a card-type SSD according to an exemplary embodiment of the inventive concept;

FIG. 11 is a schematic view of a configuration of a card-type SSD according to an exemplary embodiment of the inventive concept; and

FIG. 12 is a block diagram of an electronic system including a card-type SSD according to an exemplary embodiment of the inventive concept.

### DETAILED DESCRIPTION OF THE EMBODIMENTS

Hereinafter, exemplary embodiments of the inventive concept will be described in detail with reference to the accompanying drawings.

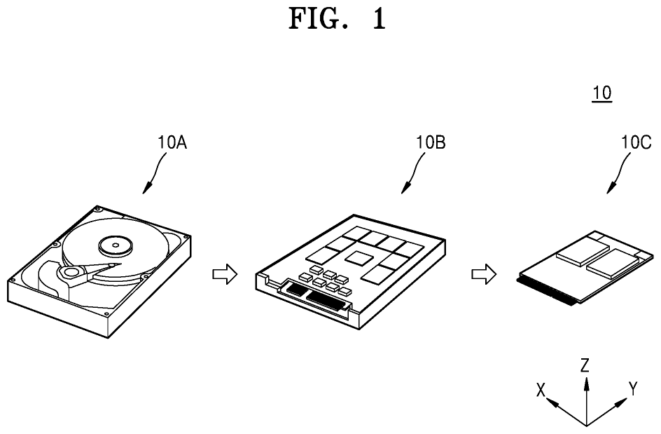

FIG. 1 is a perspective view showing examples of storage devices.

FIG. 1 shows various examples of a storage device 10 as technology has developed.

As an example of the storage device 10, a hard disk drive (HDD) 10A may include a platter for storing data in a magnetic material coated on the surface of the platter. The platter may be rotated by a spindle motor, and data may be written or read by an input/output head. As such, the size of the HDD 10A may be relatively large due to components such as a motor for rotating a platter and an input/output head for writing data to the platter. For example, the HDD 10A may have form factors of 5.25 inches, 3.5 inches, 2.5 inches, and 1.8 inches.

Over time, the storage device 10 including a semiconductor memory chip was used instead of conventional devices for data storage such as magnetic disks, magnetic tapes, optical disks, and the like. The storage device 10 including the semiconductor memory chip provided many advantages such as low power consumption, small size, and high storage capacity.

As an example of the storage device 10 according to this technology, there is provided a solid state drive (SSD) 10B including a semiconductor memory chip. For example, a semiconductor memory chip may include a flash memory as a nonvolatile memory, and may store data in memory cells included in the flash memory. The solid state drive 10B may conform to a form factor of the HDD 10A to be compatible with the HDD 10A, and may support an interface protocol of the HDD 10A.

As a size of an electronic device gradually decreases and the storage device 10 operating at a high speed is required, the storage device 10 having a smaller size than those currently existing and supporting a high-speed interface protocol is desired. Accordingly, a form factor corresponding to a relatively small size, for example, a mini-serial advanced technology attachment (mSATA) standard using a peripheral component interconnect (PCI) Express (PCIe) layout, and an M.2 standard defining flexible sizes other than the mSATA standard have been proposed.

These standards define a relatively small solid state drive 10C, as shown in FIG. 1, and the small solid state drive IOC may include at least one semiconductor package mounted on a printed circuit board.

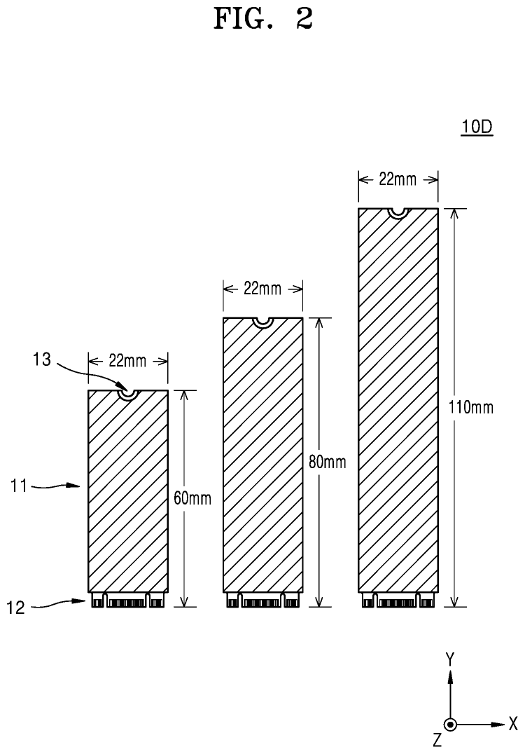

FIG. 2 is a plan view of various form factors of a solid state drive.

FIG. 2 shows thickness and left and right widths of a printed circuit board 11 constituting an M.2 standard solid state drive 10D as an example of a form factor.

The M.2 standard solid state drive 10D may define the length of the printed circuit board 11 in a first direction (X direction) to be 22 mm, and the length of the printed circuit board 11 in a second direction (Y direction) to be 60 mm, 80 mm, or 110 mm.

In addition, the M.2 standard solid state drive 10D may define a port 12. The port 12 may be located on one side of the printed circuit board 11, and may include a plurality of pins for communicating with a host. The plurality of pins may be an exposed pattern, and the exposed pattern may be connected to a socket included in the host. The plurality of pins may include a conductive material, for example, a metal such as copper.

In addition, the M.2 standard solid state drive 10D may include an indentation structure 13 for mounting and fixing the M.2 standard solid state drive 10D to the host. In other words, the M.2 standard solid state drive 10D may include a semi-circular indentation structure 13 formed on the other side of the solid state drive 10D facing the port 12. An exposed pattern may be formed on an edge of the indentation structure 13 and, when mounted on a host, may be connected to a conductor of the host. For example, a pattern formed on the edge of the indentation structure 13 may correspond to a ground node of the M.2 standard solid state drive 10D and, when mounted on a host, may be connected to a conductor corresponding to a ground node of the host.

Due to the number of mounted semiconductor packages according to different specifications and memory capacities of various main boards included in various electronic devices, the printed circuit board 11 may be manufactured to have various form factors.

However, since the M.2 standard solid state drive 10D described above is relatively thick and manufactured in a larger size than a general memory card because the M.2 standard solid state drive 10D includes the printed circuit board 11, there may be limitations to its application to an electronic device in which miniaturization and portability are emphasized, such as a portable computer or a smart phone.

To provide a solid state drive that can be applied to an electronic device in which miniaturization and portability are emphasized, exemplary embodiments of the inventive concept implement a solid state drive (hereinafter referred to as a card-type SSD) in the form of a memory card. Details of the inventive concept will be described later below.

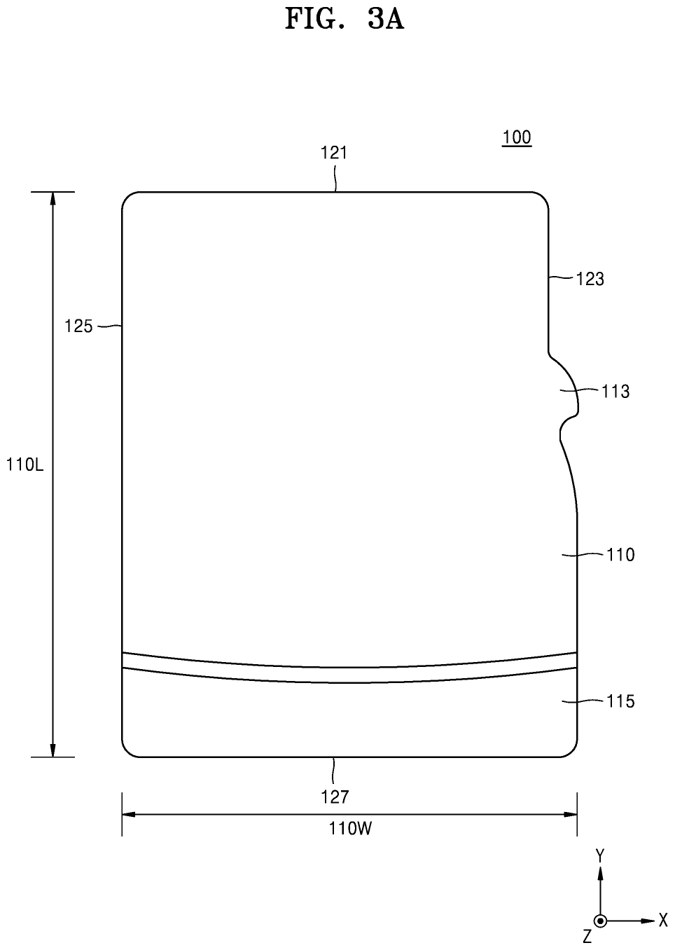

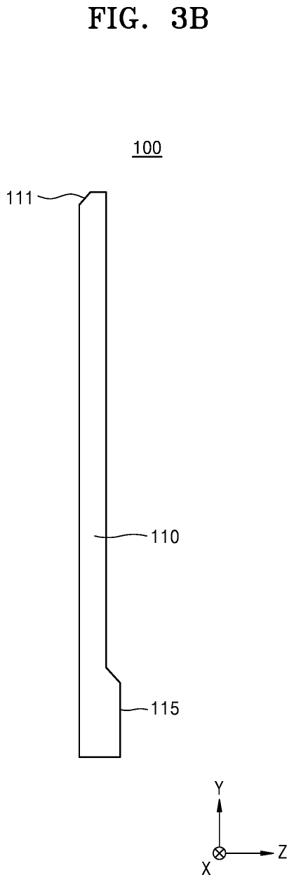

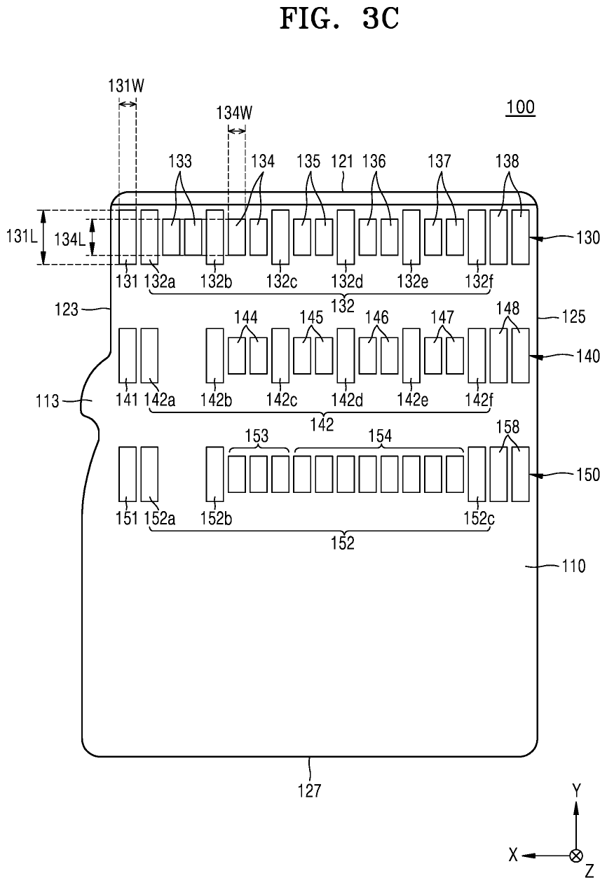

FIGS. 3A, 3B and 3C are views of a card-type SSD according to an exemplary embodiment of the inventive concept.

For example, FIG. 3A is a plan view showing a card-type SSD 100, FIG. 3B is a side view showing the card-type SSD 100, and FIG. 3C is a bottom view showing the card-type SSD 100.

FIGS. 3A to 3C show the card-type SSD 100 having a substrate 110, a protrusion 113 arranged on a first edge 123, first column terminals 130 including a first power terminal 131 and first data terminals 134, 135, 136, and 137, second column terminals 140 including a second power terminal 141 and second data terminals 144, 145, 146, and 147, and third column terminals 150 including a third power terminal 151 and command terminals 153.

The card-type SSD 100 may define a width 110W of the substrate 110 in the first direction (X direction) to be about 20 mm, and a length 110L of the substrate 110 in the second direction (Y direction) to be about 24 mm, but is not limited thereto.

The card-type SSD 100 may have two pairs of opposite edges. The two pairs of edges may have an insertion edge 121 in a direction in which the card-type SSD 100 is inserted into a socket and the first edge 123 and a second edge 125 adjacent to the insertion edge 121. The first edge 123 and the second edge 125 may be opposite each other. In addition, the card-type SSD 100 may have a leading edge 127 facing the insertion edge 121. In this case, the insertion edge 121 and the leading edge 127 may be parallel to each other.

The second edge 125 may extend in the second direction (Y direction) perpendicular to the first direction (X direction) in which the insertion edge 121 extends. Further, the second edge 125 may extend only in a single direction. Alternatively, the first edge 123 may have a portion parallel to and not parallel to the second edge 125.

In some exemplary embodiments of the inventive concept, the card-type SSD 100 may include a chamfer 111. The chamfer 111 may prevent a connection pin of a socket from being damaged when the card-type SSD 100 is inserted into the socket. For example, the connection pin of the socket has a bent end portion, and has a certain tension to maintain contact with the card-type SSD 100. When the card-type SSD 100 is inserted into the socket, the connection pin slides and moves in an inclined direction of the chamfer 111, and then, contacts a bottom surface of the card-type SSD 100 in which the first to third column terminals 130, 140, and 150 are arranged.

In some exemplary embodiments of the inventive concept, the card-type SSD 100 may include the protrusion 113 having a shape resembling a shark fin on the first edge 123. The protrusion 113 may stably mount the card-type SSD 100 in a socket. In other words, the protrusion 113 may prevent the card-type SSD 100 from being unintentionally separated from a socket by shock and vibration. In addition, the protrusion 113 may prevent the card-type SSD 100 from being incorrectly inserted into the socket.

In some exemplary embodiments of the inventive concept, the card-type SSD 100 may include a notch 115. The notch 115 is a protruding structure formed on one surface of the card-type SSD 100, and may extend from the first edge 123 to the second edge 125 in the first direction (X direction). The notch 115 may be arranged adjacent to the leading edge 127, and when the card-type SSD 100 is inserted into a socket, the notch 115 may be exposed to the outside. The notch 115 may allow a user to easily remove the card-type SSD 100 mounted on the socket. In other words, when a user pushes the notch 115 in a direction away from the socket, the card-type SSD 100 may be separated from the socket.

Between the edges 121, 123, 125, and 127, there may be corners having a certain radius of curvature. The corners may be identical to each other, or may be different from each other.

The insertion edge 121 is an edge along which the card-type SSD 100 is inserted into the socket. When the card-type SSD 100 is inserted into the socket, the insertion edge 121, from among the edges 121, 123, 125, and 127, enters the socket first, and when the card-type SSD 100 is withdrawn from the socket, the insertion edge 121, from among the edges 121, 123, 125, and 127, leaves the socket last. In order for the card-type SSD 100 to smoothly enter the inside of the socket, a width of the insertion edge 121 may be determined in consideration of a certain clearance.

Adjacent to the insertion edge 121, terminals for electrically connecting semiconductor devices and a host in the card-type SSD 100 may be arranged in a plurality of columns. The host may be, for example, a smart phone, a desktop computer, a laptop computer, a tablet computer, a game console, a navigation device, or a digital camera, but is not limited thereto. In addition, an adapter for interfacing may be located between the card-type SSD 100 and the host.

The terminals may be arranged in three columns as shown. In other words, the first column terminals 130, the second column terminals 140, and the third column terminals 150 may be sequentially arranged adjacent to the insertion edge 121 of the substrate 110. In particular, the first column terminals 130 may be arranged closest to the insertion edge 121, the second column terminals 140 may be arranged to be farther from the insertion edge 121 than the first column terminals 130, and the third column terminals 150 may be arranged to be farther from the insertion edge 121 than the second column terminals 140.

First, the configuration of the first column terminals 130 will be described in detail.

The first column terminals 130 may include the first power terminal 131 having a first voltage, and the first voltage may have a value, for example, between about 3.0 V and about 3.5 V. The first voltage may be supplied to semiconductor devices that perform a read/write operation among semiconductor devices in the card-type SSD 100. In some exemplary embodiments of the inventive concept, the first voltage may be supplied to nonvolatile memory devices in the card-type SSD 100.

The first column terminals 130 may have one or more first ground terminals 132. For example, the first column terminals 130 may have six first ground terminals 132.

The first column terminals 130 may have the first data terminals 134, 135, 136, and 137. For example, the first column terminals 130 may include a pair of first data input terminals 134, a pair of first data output terminals 135, a pair of second data input terminals 136, and a pair of second data output terminals 137. In FIG. 3C, the positions of the data input terminals 134 and 136 and the data output terminals 135 and 137 may be changed.

The first data input terminals 134 may be electrically shielded by a pair of ground terminals 132b and 132c. In addition, the first data output terminals 135 may be electrically shielded by a pair of ground terminals 132c and 132d.

Likewise, the second data input terminals 136 may be electrically shielded by a pair of ground terminals 132d and 132e. In addition, the second data output terminals 137 may be electrically shielded by a pair of ground terminals 132e and 132f. The shielding makes it possible to input and output data more stably.

In some exemplary embodiments of the inventive concept, the pair of ground terminals 132b and 132c for shielding the first data input terminals 134 and the pair of ground terminals 132c and 132d for shielding the first data output terminals 135 may share one ground terminal 132c. For example, the ground terminal 132c may be disposed between one of the first data input terminals 134 and one of the first data output terminals 135. Similarly, the pair of ground terminals 132d and 132e for shielding the second data input terminals 136 and the pair of ground terminals 132e and 132f for shielding the second data output terminals 137 may share one ground terminal 132e. In addition, the pair of ground terminals 132c and 132d for shielding the first data output terminals 135 and the pair of ground terminals 132d and 132e for shielding the second data input terminals 136 may share one ground terminal 132d.

In other exemplary embodiments of the inventive concept, ground terminals for shielding the data input terminals 134 and 136 and ground terminals for shielding the data output terminals 135 and 137 may not have a ground terminal shared with each other.

The first data input terminals 134 and the second data input terminals 136 may have the same dimensions as each other. In addition, the first data output terminals 135 and the second data output terminals 137 may have the same dimensions as each other. In some exemplary embodiments of the inventive concept, the first data terminals 134, 135, 136, and 137 may all have the same dimensions as each other. In the alternative, the first data terminals 134, 135, 136, and 137 may have different dimensions with respect to each other.

A first length 131L in the second direction (Y direction) of the first power terminal 131 may be greater than a second length 134L in the second direction (Y direction) of the first data terminals 134, 135, 136, and 137. For example, the first length 131L may be from about 2 mm to about 3 mm, and the second length 134 L may be from about 1.3 mm to about 1.7 mm, but is not limited thereto.

In other words, the first data terminals 134, 135, 136, and 137 may not deviate from the first power terminal 131 in the second direction (Y direction) perpendicular to the insertion edge 121. In other words, individual ones of the first data terminals 134, 135, 136, and 137 may not be longer than the first power terminal 131 in the second direction (Y direction). Further, the first data terminals 134, 135, 136, and 137 may not deviate from the first ground terminals 132a, 132b, 132c, 132d, 132e, and 132f in the second direction (Y direction).

In particular, a front end of the first power terminal 131 adjacent to the insertion edge 121 may be closer to the insertion edge 121 than a front end of the first data terminals 134, 135, 136, and 137 adjacent the insertion edge 121. In addition, a back end of the first power terminal 131 opposite the front end of the first power terminal 131 may be closer to the leading edge 127 than a back end of the first data terminals 134, 135, 136, and 137 opposite the front end of the first data terminals 134, 135, 136, and 137.

The first column terminals 130 may have a pair of reference clock terminals 133. The reference clock terminals 133 may be provided with a clock signal having a frequency of, for example, about 26 MHz. A ground terminal 132a may be between the reference clock terminals 133 and the first power terminal 131. By this configuration, the reference clock terminals 133 may be electrically shielded from signal input/output of the neighboring first data terminals 134, 135, 136, and 137 by the ground terminals 132a and 132b, thereby enabling more stable operation.

In addition, a distance from the insertion edge 121 of the reference clock terminals 133 may be minimized for a high-speed operation. Since the location of a memory controller included in the card-type SSD 100 may be changed according to the design of the card-type SSD 100, the reference clock terminals 133 may continue to be located in the first column terminals 130 for high-speed operation.

Further, the first column terminals 130 may include one or more first spare terminals 138. At least one of the first spare terminals 138 may perform the same function as that of the first power terminal 131. Therefore, the first spare terminals 138 may have the same size and number as that of the first power terminal 131.

Next, the configuration of the second column terminals 140 will be described in more detail.

The second column terminals 140 may include the second power terminal 141 having a second voltage, and the second voltage may have a value, for example, between about 3.0 V and about 3.5 V. In other words, the second voltage may be substantially the same as the first voltage. The second voltage may be supplied to semiconductor devices that perform a read/write operation among semiconductor devices in the card-type SSD 100. In some exemplary embodiments of the inventive concept, the second voltage may be supplied to nonvolatile memory devices in the card-type SSD 100.

The second column terminals 140 may have one or more second ground terminals 142. For example, the second column terminals 140 may have six second ground terminals 142.

The second column terminals 140 may have the second data terminals 144, 145, 146, and 147. For example, the second column terminals 140 may include a pair of third data input terminals 144, a pair of third data output terminals 145, a pair of fourth data input terminals 146, and a pair of fourth data output terminals 147. In FIG. 3C, the positions of the data input terminals 144 and 146 and the data output terminals 145 and 147 may be changed.

The third data input terminals 144 may be electrically shielded by a pair of ground terminals 142b and 142c. In addition, the third data output terminals 145 may be electrically shielded by a pair of ground terminals 142c and 142d.

Likewise, the fourth data input terminals 146 may be electrically shielded by a pair of ground terminals 142d and 142e. In addition, the fourth data output terminals 147 may be electrically shielded by a pair of ground terminals 142e and 142f. The shielding makes it possible to input and output data more stably.

In exemplary embodiments of the inventive concept, the pair of ground terminals 142b and 142c for shielding the third data input terminals 144 and the pair of ground terminals 142c and 142d for shielding the third data output terminals 145 may share one ground terminal 142c. Similarly, the pair of ground terminals 142d and 142e for shielding the fourth data input terminals 146 and the pair of ground terminals 142e and 142f for shielding the fourth data output terminals 147 may share one ground terminal 142e. In addition, the pair of ground terminals 142c and 142d for shielding the third data output terminals 145 and the pair of ground terminals 142d and 142e for shielding the fourth data input terminals 146 may share one ground terminal 142d.

In other exemplary embodiments of the inventive concept, ground terminals for shielding the data input terminals 144 and 146 and ground terminals for shielding the data output terminals 145 and 147 may not have a ground terminal shared with each other. For example, one of the ground terminals 142c to 142e may be removed.

The third data input terminals 144 and the fourth data input terminals 146 may have the same dimensions as each other. In addition, the third data output terminals 145 and the fourth data output terminals 147 may have the same dimensions as each other. In some exemplary embodiments of the inventive concept, the second data terminals 144, 145, 146, and 147 may all have the same dimensions as each other. In the alternative, the second data terminals 144, 145, 146, and 147 may have different dimensions with respect to each other.

A length of the second power terminal 141 in the second direction (Y direction) may be greater than lengths of the second data terminals 144, 145, 146, and 147 in the second direction (Y direction). For example, the length of the second power terminal 141 may be from about 2 mm to about 3 mm, and the lengths of the second data terminals 144, 145, 146, and 147 may be from about 1.3 mm to about 1.7 mm, but is not limited thereto.

In other words, in the second direction (Y direction) perpendicular to the insertion edge 121, the second data terminals 144, 145, 146, and 147 may not deviate from the second power terminal 141. Further, in the second direction (Y direction), the second data terminals 144, 145, 146, and 147 may not deviate from the second ground terminals 142a, 142b, 142c, 142d, 142e, and 142f.

In particular, a front end of the second power terminal 141 adjacent to the insertion edge 121 may be closer to the insertion edge 121 than a front end of the second data terminals 144, 145, 146, and 147 adjacent to the insertion edge 121. In addition, a back end of the second power terminal 131 facing the front end of the second power terminal 131 may be closer to the leading edge 127 than a back end of the second data terminals 144, 145, 146, and 147 facing the front end of the second data terminals 144, 145, 146, and 147.

Unlike the first column terminals 130, the second column terminals 140 may not have terminals in an area corresponding to an area where the reference clock terminals 133 are arranged. In other words, the space between the ground terminals 142a and 142b may be free of terminals.

Further, the second column terminals 140 may include one or more second spare terminals 148. At least one of the second spare terminals 148 may perform the same function as that of the second power terminal 141. Therefore, the second spare terminals 148 may have the same size and number as that of the second power terminal 141.

Lastly, the configuration of the third column terminals 150 will be described in more detail.

The third column terminals 150 may include the third power terminal 151 having a third voltage, and the third voltage may have a value, for example, between about 3.0 V and about 3.5 V. In some exemplary embodiments of the inventive concept, the third voltage may be substantially the same as the first voltage and the second voltage. In other exemplary embodiments of the inventive concept, the third voltage may be different from the first and second voltages. The third voltage may be supplied to semiconductor devices that perform a control operation among the semiconductor devices in the card-type SSD 100. In some exemplary embodiments of the inventive concept, the third voltage may be supplied to a memory controller in the card-type SSD 100.

The third column terminals 150 may have one or more third ground terminals 152. For example, the third column terminals 150 may have three ground terminals 152.

The third column terminals 150 may have the command terminals 153 and test terminals 154. In FIG. 3C, although the command terminals 153 are shown closer to the third power terminal 151 than the test terminals 154, their positions may be changed.

The command terminals 153 and the test terminals 154 may be electrically shielded by a pair of ground terminals 152b and 152c. Commands and tests may be more stably performed by the shielding.

The command terminals 153 and the test terminals 154 may have the same dimensions as each other. A length of the third power terminal 151 in the second direction (Y direction) may be greater than lengths of the command terminals 153 and the test terminals 154 in the second direction (Y direction). For example, the length of the third power terminal 151 may be from about 2 mm to about 3 mm, and the lengths of the command terminals 153 and the test terminals 154 may be from about 1.3 mm to about 1.7 mm, but is not limited thereto.

The command terminals 153 and the test terminals 154 may be provided in different numbers. As illustrated, the test terminals 154 may be provided more in number than the command terminals 153, but is not limited thereto.

In the second direction (Y direction) perpendicular to the insertion edge 121, the command terminals 153 and the test terminals 154 may not deviate from the third power terminal 151. Further, in the second direction (Y direction), the command terminals 153 and the test terminals 154 may not deviate from the third ground terminals 152a, 152b, and 152c.

The lengths of the command terminals 153 and the test terminals 154 in the second direction (Y direction) may be less than the length of the third power terminal 151 in the second direction (Y direction). In particular, a front end of the third power terminal 151 may be closer to the insertion edge 121 than a front end of the command terminals 153 and the test terminals 154. In addition, a back end of the third power terminal 151 may be closer to the leading edge 127 than a back end of the command terminals 153 and the test terminals 154.

Unlike the first column terminals 130, the third column terminals 150 may not be arranged in an area corresponding to an area where the reference clock terminals 133 are arranged. In other words, the space between the ground terminals 152a and 152b may be empty.

Further, the third column terminals 150 may include one or more third spare terminals 158. At least one of the third spare terminals 158 may perform the same function as that of the third power terminal 151. Therefore, the third spare terminals 158 may have the same size and number as that of the third power terminal 151.

The first to third power terminals 131, 141, and 151 may be linearly arranged in the second direction (Y direction) adjacent to the first edge 123. In other words, the first to third column terminals 130, 140, and 150 may be configured such that power terminals are arranged in the same position in each column. Accordingly, electrically stable power may be supplied to the nonvolatile memory device and the memory controller.

A connection wiring pattern may also be disposed between the nonvolatile memory device and the first and second power terminals 131 and 141. In addition, a connection wiring pattern may be disposed between the memory controller and the third power terminal 151. For example, the first, second and third power terminals 131, 141 and 151 may be connected to each other. A connection wiring pattern may also be disposed between the nonvolatile memory device and the first to third spare terminals 138, 148 and 158.

In some exemplary embodiments of the inventive concept, since the first column terminals 130 are located closer to the insertion edge 121 than the second and third column terminals 140 and 150, power may be supplied to the first column terminals 130 before the second and third column terminals 140 and 150. In other words, as the card-type SSD 100 is inserted, power of a first voltage is first supplied to nonvolatile memory devices through the first power terminal 131 included in the first column terminals 130. In addition, since the first ground terminals 132 of the first column terminals 130 are also connected to a host in advance, power and a ground circuit capable of operating the entire card-type SSD 100 are formed before the power is supplied to the memory controller, thereby preparing the card-type SSD 100 overall operation.

The first to third spare terminals 138, 148, and 158 may be arranged in a line in the second direction (Y direction) adjacent to the second edge 125. In other words, the first to third column terminals 130, 140, and 150 may be configured such that spare terminals are arranged in the same position in each column. When the first to third spare terminals 138, 148, and 158 serve as power supply, electrically stable backup power may be supplied to the nonvolatile memory device and the memory controller.

Although FIG. 3C shows that the number of first column terminals 130 are 19, the second column terminals 140 are 17, and the third column terminals 150 are 17, the number, location, shape, and size of the terminals are not limited thereto, and may be changed as desired. In addition, some terminals of the third column terminals 150 may not be exposed to the outside by being covered by a solder resist (SR) layer. Some of the terminals that are not exposed may be, for example, the test terminals 154.

Terminals constituting the first to third column terminals 130, 140, and 150 have first widths 131W and 134W substantially the same in the first direction, respectively, and the first widths 131W and 134W are from about 0.5 mm to about 0.9 mm. However, the inventive concept is not limited thereto.

The first to third column terminals 130, 140, and 150 may include an input/output terminal structure conforming to the 4 lane standard of PCIe. In other words, the first column terminals 130 may include the first data input terminals 134, the first data output terminals 135, the second data input terminals 136, and the second data output terminals 137, and the second column terminals 140 may include the third data input terminals 144, the third data output terminals 145, the fourth data input terminals 146, and the fourth data output terminals 147. The first to fourth data input terminals 134, 136, 144, and 146 and the first to fourth data output terminals 135, 137, 145, and 147 may meet the 4 lane standard of PCIe.

Therefore, since the card-type SSD 100 according to an exemplary embodiment of the inventive concept may include an input/output terminal structure according to the 4 lane standard of PCIe, a solid state drive may be implemented with a small size similar to a general memory card.

In addition, the card-type SSD 100 according to an exemplary embodiment of the inventive concept may be configured to include the first to third power terminals 131, 141, and 151 in each of the first to third column terminals 130, 140, and 150 to maximize the utilization of a card area and to provide electrically stable power supply.

Thus, for example, the card-type SSD 100 according to an exemplary the embodiment of the inventive concept has both portability and stability.

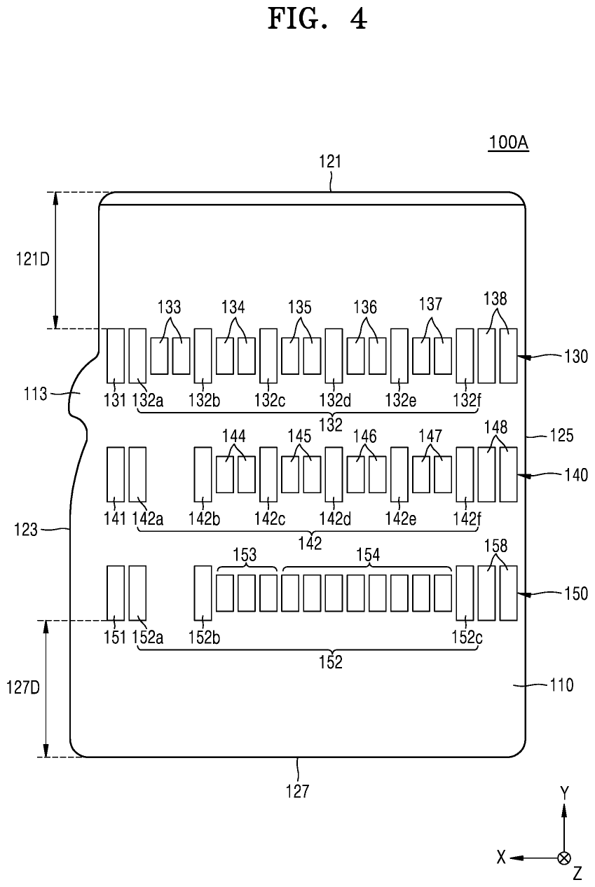

FIGS. 4 to 9 are bottom views of a card-type SSD according to an exemplary embodiment of the inventive concept, respectively.

Most components constituting card-type SSDs 100A, 100B, 100C, 100D, 100E, and 100F described below and the contents constituting the components are substantially the same or similar to those described with reference to FIGS. 3A to 3C. Therefore, to prevent overlapping description, a difference from the card-type SSD 100 described above will be mainly described.

FIG. 4 shows the card-type SSD 100A having the substrate 110, the first column terminals 130 including the first power terminal 131 and the first data terminals 134, 135, 136, and 137, the second column terminals 140 including the second power terminal 141 and the second data terminals 144, 145, 146, and 147, and the third column terminals 150 including the third power terminal 151 and the command terminals 153.

The first column terminals 130 may be arranged adjacent to the insertion edge 121, the second column terminals 140 may be arranged to be farther from the insertion edge 121 than the first column terminals 130, and the third column terminals 150 may be arranged to be farther from the insertion edge 121 than the second column terminals 140.

In the second direction (Y direction), the insertion edge 121 to the first column terminals 130 may be separated by a first distance 121D, and the leading edge 127 to the third column terminals 150 may be separated by a third distance 127D. The first distance 121D may be substantially the same as the third distance 127D.

In other words, in the card-type SSD 100A according to the present embodiment, the first to third column terminals 130, 140, and 150 may be arranged in the center of the substrate 110.

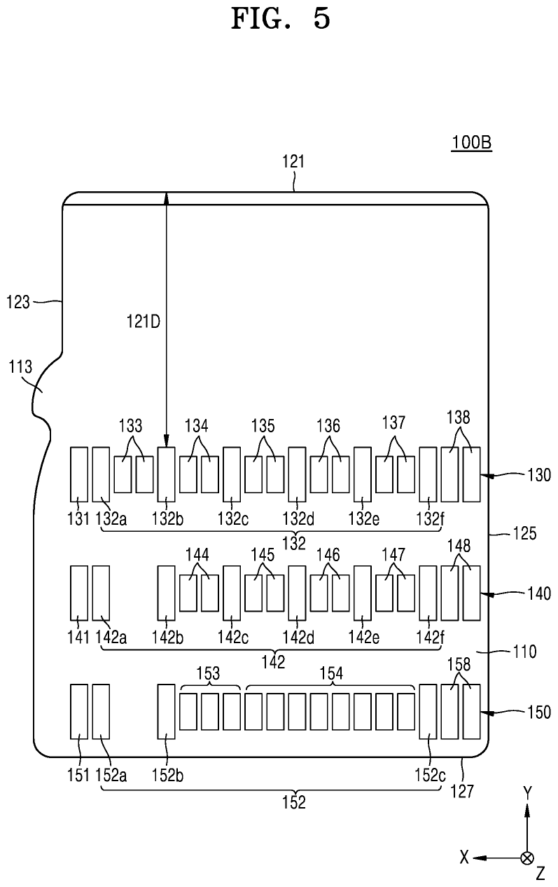

FIG. 5 shows the card-type SSD 100B having the substrate 110, the protrusion 113 arranged on the first edge 123, the first column terminals 130 including the first power terminal 131 and the first data terminals 134, 135, 136, and 137, the second column terminals 140 including the second power terminal 141 and the second data terminals 144, 145, 146, and 147, and the third column terminals 150 including the third power terminal 151 and the command terminals 153.

The third column terminals 150 may be arranged adjacent to the leading edge 127, the second column terminals 140 may be arranged to be farther from the leading edge 127 than the third column terminals 150, and the first column terminals 130 may be arranged to be farther from the leading edge 127 than the second column terminals 140.

In the second direction (Y direction), a first distance 121D may separate the insertion edge 121 and the first column terminals 130, and the first distance 121D may be longer than a distance from the insertion edge 121 to the protrusion 113.

In other words, in the card-type SSD 100B according to the present embodiment, the first to third column terminals 130, 140, and 150 may be arranged at a lower end of the substrate 110.

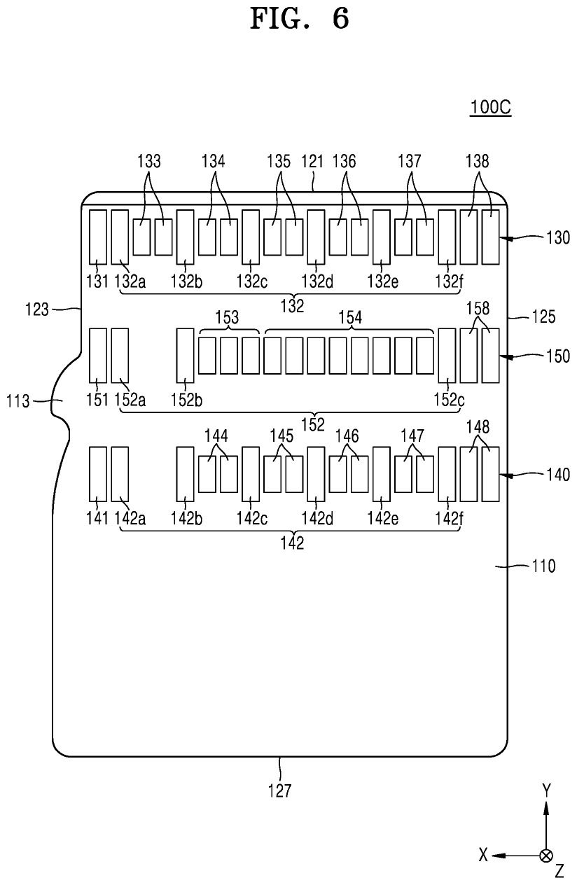

FIG. 6 shows the card-type SSD 100C having the substrate 110, the first column terminals 130 including the first power terminal 131 and the first data terminals 134, 135, 136, and 137, the second column terminals 140 including the second power terminal 141 and the second data terminals 144, 145, 146, and 147, and the third column terminals 150 including the third power terminal 151 and the command terminals 153.

The first column terminals 130 may be arranged adjacent to the insertion edge 121, the third column terminals 150 may be arranged to be farther apart from the insertion edge 121 than the first column terminals 130, and the second column terminals 140 may be arranged to be farther apart from the insertion edge 121 than the third column terminals 150.

In other words, in the card-type SSD 100C according to the present embodiment, the third column terminals 150 may be between the first column terminals 130 and the second column terminals 140.

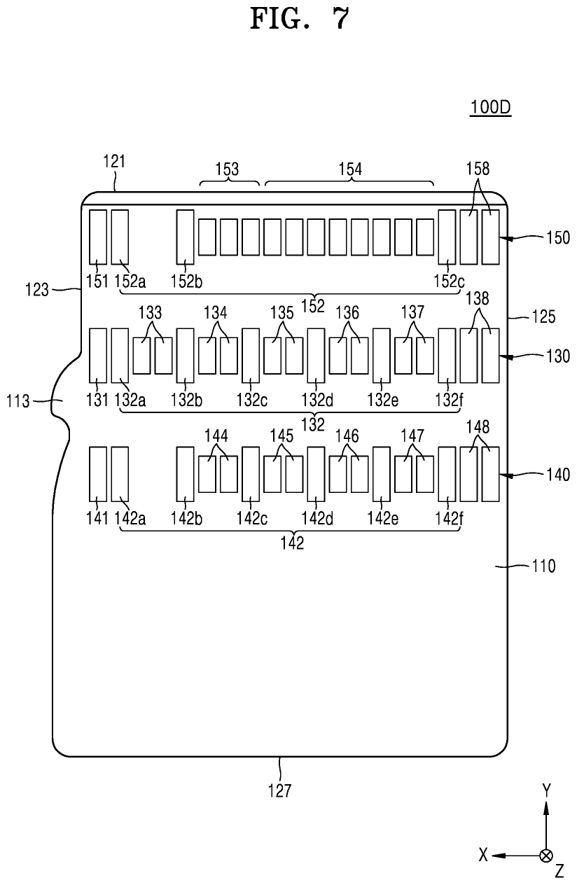

FIG. 7 shows the card-type SSD 100D having the substrate 110, the first column terminals 130 including the first power terminal 131 and the first data terminals 134, 135, 136, and 137, the second column terminals 140 including the second power terminal 141 and the second data terminals 144, 145, 146, and 147, and the third column terminals 150 including the third power terminal 151 and the command terminals 153.

The third column terminals 150 may be arranged adjacent to the insertion edge 121, the first column terminals 130 may be arranged to be farther apart from the insertion edge 121 than the third column terminals 150, and the second column terminals 140 may be arranged to be farther apart from the insertion edge 121 than the first column terminals 130.

In other words, in the card-type SSD 100D according to the present embodiment, the first column terminals 130 may be between the third column terminals 150 and the second column terminals 140.

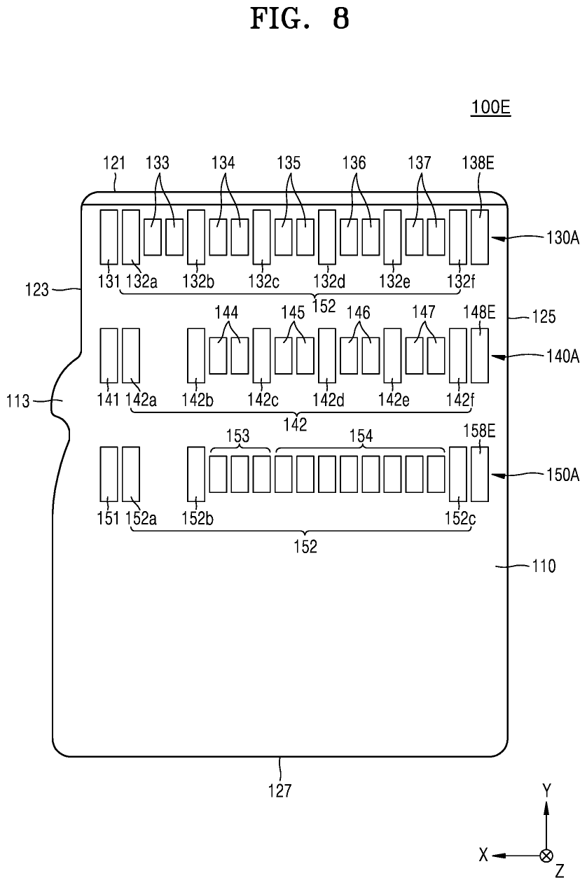

FIG. 8 shows the card-type SSD 100E having the substrate 110, first column terminals 130A including the first power terminal 131 and the first data terminals 134, 135, 136, and 137, second column terminals 140A including the second power terminal 141 and the second data terminals 144, 145, 146, and 147, and third column terminals 150A including the third power terminal 151 and the command terminals 153.

Each of the first to third column terminals 130A, 140A, and 150A may have one of first, second and third spare terminals 138E, 148E, and 158E, respectively. The first to third spare terminals 138E, 148E, and 158E may perform the same functions as those of the first to third power terminals 131, 141, and 151. Accordingly, the first to third spare terminals 138E, 148E, and 158E may have the same size and number as those of the first to third power terminals 131, 141, and 151.

The first to third spare terminals 138E, 148E, and 158E may be arranged in a line in the second direction (Y direction) adjacent to the second edge 125. In other words, the first to third column terminals 130, 140, and 150 may be configured such that spare terminals are arranged in the same position in each column. The first to third spare terminals 138E, 148E, and 158E may be capable of supplying electrically stable backup power to a nonvolatile memory device and a memory controller included in the card-type SSD 100E.

In other words, one of the first to third spare terminals 138E, 148E, and 158E corresponding to each of the first to third column terminals 130, 140, and 150 may be arranged in the card-type SSD 100E according to an exemplary embodiment of the inventive concept.

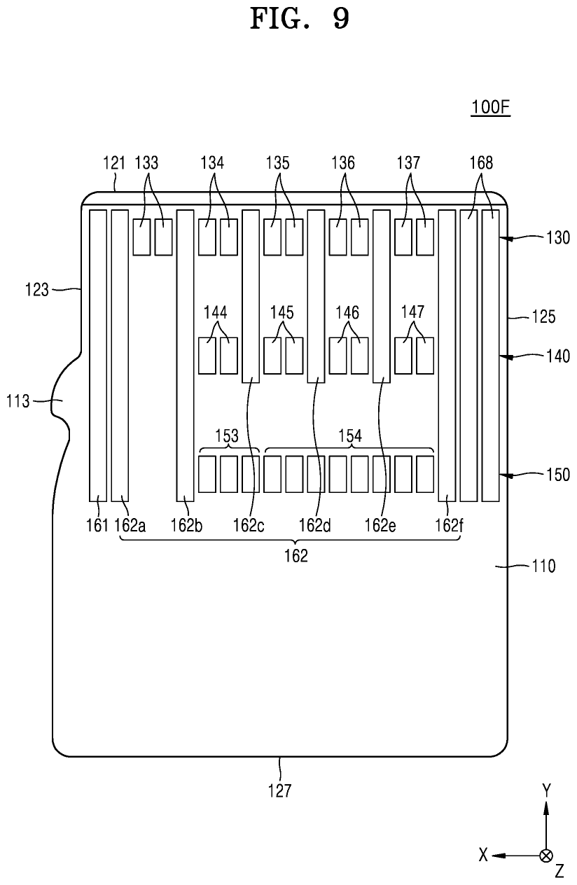

FIG. 9 shows the card-type SSD 100F having the substrate 110, the first column terminals 130 including an integrated power terminal 161 and the first data terminals 134, 135, 136, and 137, the second column terminals 140 including the integrated power terminal 161 and the second data terminals 144, 145, 146, and 147, and the third column terminals 150 including the integrated power terminal 161 and the command terminals 153.

The first to third column terminals 130, 140, and 150 may share one integrated power terminal 161. In addition, the first to third column terminals 130, 140, and 150 may share a plurality of integrated ground terminals 162. In addition, the first to third column terminals 130, 140 and 150 may share one or more integrated spare terminals 168.

The plurality of integrated ground terminals 162 may include integrated ground terminals 162a, 162b, and 162f shared by the first to third column terminals 130, 140, and 150, and integrated ground terminals 162c, 162d, and 162e shared by the first and second column terminals 130 and 140.

In other words, in the card-type SSD 100F according to the present embodiment, the first to third column terminals 130, 140, and 150 may be arranged to share the integrated power terminal 161, the integrated ground terminals 162, and the integrated spare terminal 168.

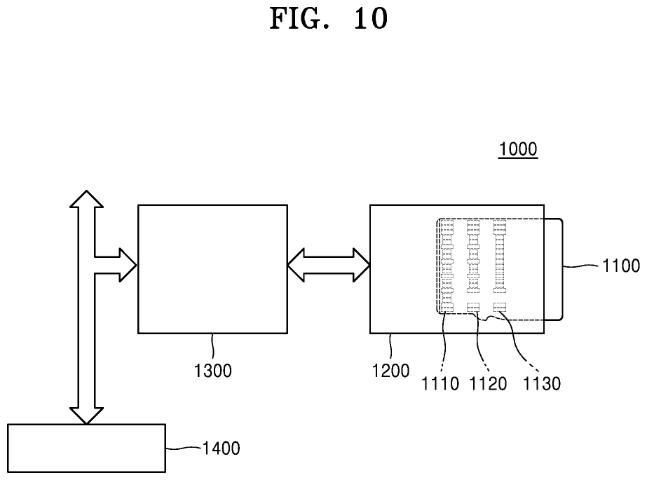

FIG. 10 is a schematic view of a system using a card-type SSD according to an exemplary embodiment of the inventive concept.

Referring to FIG. 10, a system 1000 may include a card-type SSD 1100, a socket 1200, a controller 1300, and a host 1400.

The card-type SSD 1100 may include any one of the card-type SSDs 100, 100A, 100B, 100C, 100D, 100E, and 100F according to the exemplary embodiments of the inventive concept described above.

The socket 1200 is capable of inserting the card-type SSD 1100, and may be configured to include a socket pin that is electrically connected to first column terminals 1110, second column terminals 1120, and third column terminals of the card-type SSD 1100.

The controller 1300 may control data exchange with the card-type SSD 1100 through the socket 1200. The controller 1300 may also be used to store data in the card-type SSD 1100.

The host 1400 may be, for example, an electronic device such as a smart phone, a desktop computer, a notebook computer, a tablet computer, a game console, a navigation device, or a digital camera, but is not limited thereto.

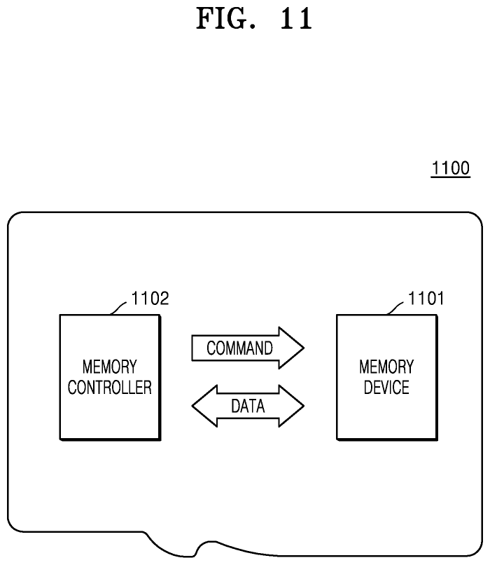

FIG. 11 is a schematic view of a configuration of a card-type SSD according to an exemplary embodiment of the inventive concept.

Referring to FIG. 11, a memory device 1101 and a memory controller 1102 in the card-type SSD 1100 may be arranged to exchange electrical signals.

In some exemplary embodiments of the inventive concept, when the memory controller 1102 commands, the memory device 1101 may transmit data.

The memory device 1101 may include a memory array or a memory array bank. The card-type SSD 1100 may include any one of the card-type SSDs 100, 100A, 100B, 100C, 100D, 100E, and 100F according to the exemplary embodiments of the inventive concept described above.

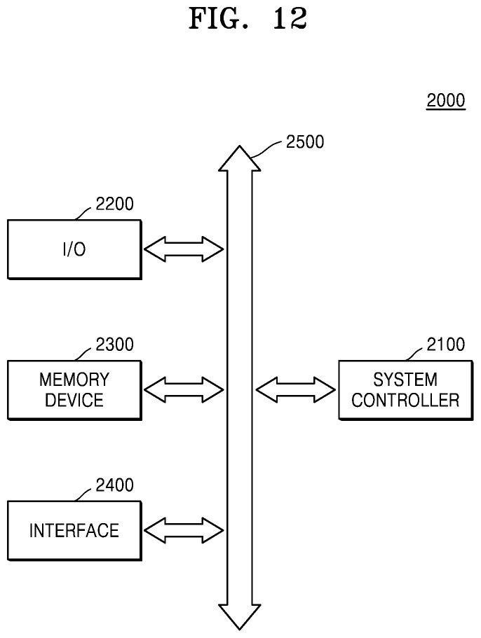

FIG. 12 is a block diagram of an electronic system including a card-type SSD according to an exemplary embodiment of the inventive concept.

Referring to FIG. 12, an electronic system 2000 may include a system controller 2100, an input/output device 2200, a memory device 2300, an interface 2400, and a bus 2500.

The system controller 2100, the input/output device 2200, the memory device 2300, and/or the interface 2400 may be electrically coupled to each other through the bus 2500. The bus 2500 may correspond to a path through which data is moved.

The system controller 2100 may include at least one of a microprocessor, a digital signal processor, a microcontroller, and logic devices capable of performing similar functions.

The input/output device 2200 may include at least one of a keypad, a keyboard, a touchpad, a touch screen, a display device, a printer, and devices capable of performing similar functions.

The memory device 2300 may store data and/or commands. The memory device 2300 may include any one of the card-type SSDs 100, 100A, 100B, 100C, 100D, 100E, and 100F according to the exemplary embodiments of the inventive concept described above. In addition, the memory device 2300 may further include other types of memory devices.

The interface 2400 may perform a function of transmitting or receiving data to or from a communication network. The interface 2400 may be wired or wireless. For example, the interface 2400 may include an antenna, Wi-Fi, or a wired/wireless transceiver.

The electronic system 2000 may further include an operational memory device for improving the operation of the system controller 2100. Further, the electronic system 2000 may be applied to a smart phone, a desktop computer, a laptop computer, a tablet computer, a game console, a navigation device, a digital camera, or any electronic device capable of transmitting and/or receiving information in wired or wireless conditions.

While the inventive concept has been particularly shown and described with reference to exemplary embodiments thereof, it will be understood that various changes in form and details may be made thereto without departing from the spirit and scope of the inventive concept as set forth in the following claims.

1. A card-type solid state drive (SSD), comprising:
a substrate having an insertion edge, a first edge, and a second edge, wherein the first edge and the second edge are adjacent to the insertion edge;
a protrusion on the first edge;
first column terminals adjacent to the insertion edge and comprising a first power terminal and first data terminals;
second column terminals farther apart from the insertion edge than the first column terminals and comprising a second power terminal and second data terminals; and
third column terminals farther apart from the insertion edge than the second column terminals and comprising a third power terminal and command terminals,
wherein the first, second and third power terminals are arranged along the first edge.

2. The card-type SSD of claim 1, wherein the first data terminals comprise a pair of first data input terminals, a pair of first data output terminals, a pair of second data input terminals, and a pair of second data output terminals, and
the second data terminals comprise a pair of third data input terminals, a pair of third data output terminals, a pair of fourth data input terminals, and a pair of fourth data output terminals.

3. The card-type SSD of claim 2, wherein the first power terminal, the first data input terminals, the first data output terminals, the second data input terminals, and the second data output terminals are spaced apart from each other with a first ground terminal therebetween, and
the second power terminal, the third data input terminals, the third data output terminals, the fourth data input terminals, and the fourth data output terminals are spaced apart from each other with a second ground terminal therebetween.

4. The card-type SSD of claim 2, wherein the first column terminals further comprise a pair of reference clock terminals, and
the reference clock terminals are between the first power terminal and the first data input terminals.

5. The card-type SSD of claim 4, wherein each of the second and third column terminals does not have terminals in an area corresponding to an area where the reference clock terminals are arranged.

6. The card-type SSD of claim 5, wherein the total number of terminals in the first column terminals is greater than the total number of terminals in the second column terminals,
the total number of terminals in the first column terminals is greater than the total number of terminals in the third column terminals, and
the total number of terminals in the second column terminals is greater than or equal to the total number of terminals in the third column terminals.

7. The card-type SSD of claim 1, wherein the first column terminals further comprise at least one first spare terminal,
the second column terminals further comprise at least one second spare terminal, and
the third column terminals further comprise at least one third spare terminal,
wherein the first, second and third spare terminals are arranged along the second edge.

8. The card-type SSD of claim 7, wherein each of the first, second and third spare terminals is a power terminal.

9. The card-type SSD of claim 1, wherein the substrate has a leading edge facing the insertion edge,
a first end of the first power terminal is closer to the insertion edge than a first end of the first data terminals, a first end of the second power terminal is closer to the insertion edge than a first end of the second data terminals and a first end of the third power terminal is closer to the insertion edge than a first end of the command terminals, and
a second end of the first power terminal is closer to the leading edge than a second end of the first data terminals, a second end of the second power terminal is closer to the leading edge than a second end of the second data terminals and a second end of the third power terminal is closer to the leading edge than a second end of the command terminals.

10. The card-type SSD of claim 1, wherein the third column terminals further comprise at least one test terminal,
the at least one test terminal is adjacent to the command terminals,
a third ground terminal is between the third power terminal and the command terminals, and
no ground terminal is between the at least one test terminal and the command terminals.

11. A card-type solid state drive (SSD), comprising:
a substrate having an insertion edge extending in a first direction, a first edge, and a second edge, wherein the first edge and the second edge are adjacent to the insertion edge and extend in a second direction perpendicular to the first direction;
a protrusion on the first edge;
first column terminals linearly arranged in the first direction and comprising a first power terminal and first data terminals;
second column terminals spaced apart from the first column terminals in the second direction, linearly arranged in the first direction, and comprising a second power terminal and second data terminals; and
third column terminals spaced apart from the first and second column terminals in the second direction, linearly arranged in the first direction, and comprising a third power terminal and command terminals,
wherein the first, second and third power terminals are linearly arranged in the second direction.

12-16. (canceled)

17. The card-type SSD of claim 11, wherein the first column terminals further comprise one or more first spare terminals,
the second column terminals further comprise one or more second spare terminals, and
the third column terminals further comprise one or more third spare terminals,
wherein the first, second and third spare terminals are linearly arranged in the second direction.

18. The card-type SSD of claim 17, wherein the first, second and third power terminals are physically connected to each other and
the first, second and third spare terminals are physically connected to each other.

19. The card-type SSD of claim 11, wherein centers of the first column terminals are linearly arranged in the first direction,
centers of the second column terminals are linearly arranged in the first direction,
centers of the third column terminals are linearly arranged in the first direction,
the first, second and third power terminals each have a first length substantially equal to each other in the second direction, and
the first and second data terminals and the command terminals each have a second length substantially equal to each other in the second direction,
wherein the first length is greater than the second length.

20. The card-type SSD of claim 11, wherein the first data terminals comprise a pair of first data input terminals, a pair of first data output terminals, a pair of second data input terminals, and a pair of second data output terminals, and
the second data terminals comprise a pair of third data input terminals, a pair of third data output terminals, a pair of fourth data input terminals, and a pair of fourth data output terminals.

21. A card-type solid state drive (SSD), comprising:
a substrate having an insertion edge extending in a first direction, a first edge, and a second edge, wherein the first edge and the second are adjacent to the insertion edge and extend in a second direction perpendicular to the first direction;
a protrusion on the first edge;
first column terminals arranged adjacent to the insertion edge and comprising a first power terminal, a reference clock terminal, first data terminals, and a first spare terminal;
second column terminals arranged farther apart from the insertion edge than the first column terminals and comprising a second power terminal, second data terminals, and a second spare terminal; and
third column terminals arranged farther apart from the insertion edge than the second column terminals and comprising third power terminals, command terminals, test terminals, and a third spare terminal,
wherein the first, second and third power terminals are linearly arranged in the second direction and are adjacent to the first edge.

22. The card-type SSD of claim 21, wherein a length of the substrate in the first direction is about 20 mm, and
a length of the substrate in the second direction is about 24 mm.

23. The card-type SSD of claim 21, wherein centers of the first column terminals are linearly arranged in the first direction,
centers of the second column terminals are linearly arranged in the first direction,
centers of the third column terminals are linearly arranged in the first direction,
the first, second and third power terminals and the first, second and third spare terminals each have a first length substantially equal to each other in the second direction, and
the reference clock terminal, the first and second data terminals, the command terminals, and the test terminals each have a second length substantially equal to each other in the second direction,
wherein the first length is greater than the second length.

24. The card-type SSD of claim 23, wherein the first length is about 2 mm to about 3 mm, and
the second length is about 1.3 mm to about 1.7 mm.

25. The card-type SSD of claim 21, wherein terminals of the first, second and third column terminals each have a first width substantially equal to each other in the first direction, and
the first width is about 0.5 mm to about 0.9 mm.

26-30. (canceled)
